(19) United States
(12) Patent Application Publication
(10) Pub. No.: US 2009/0207464 A1
(43) Pub. Date: Aug. 20, 2009

(54) Holograms and Hologram Fabrication Methods and Apparatus

(76) Inventors: John David Wiltshire, Essex (GB); David Roy Winterbottom, Essex (GB)

Correspondence Address: TAROLLI, SUNDHEIM, COVELL & TUMMINO L.L.P., 1300 EAST NINTH STREET, SUITE 1700, CLEVEVLAND, OH, 44114, US

(21) Appl. No.: 11/719,642

(22) PCT Filed: Nov. 21, 2005
(86) PCT No.: PCT/GB2005/050208

§ 371 Date: Mar. 23, 2009

Related U.S. Application Data
(60) Provisional application No. 60/651,614, filed on Feb. 11, 2005.
(60) Provisional application No. 60/651,615, filed on Feb. 11, 2005.

(30) Foreign Application Priority Data
Nov. 24, 2004 (GB) 0425831.5
Dec. 3, 2004 (GB) 0426571.6

(51) Int. Cl. G03H 1/00; G03F 7/20

(52) U.S. Cl. 359/2; 430/2

(57) ABSTRACT

This invention relates to improved methods of fabricating hologram systems, in particular holograms on a substrate such as a security document or bank note, to hologram systems fabricated by the described methods, and to starting materials for the methods.

A method of preparing a hologram on a substrate, the method comprising: providing a hologram recording medium, the material comprising a carrier bearing a photosensitive hologram recording layer; recording a hologram in said photosensitive hologram recording layer; applying an adhesive to said hologram recording layer; attaching said carrier bearing said hologram recording layer to a substrate using said adhesive; and removing said carrier to leave said hologram recording layer attached to said substrate by said adhesive.

This invention relates to improved, methods and apparatus for fabricating hologram systems, in particular holograms on a substrate such as a security document or bank note, to hologram systems fabricated by the described methods, and to starting materials for the methods.

A well known conventional process for applying a hologram to a document or other substrate is the so-called hot foiling process, which employs a wax melt release layer to apply an embossed hologram to the substrate.

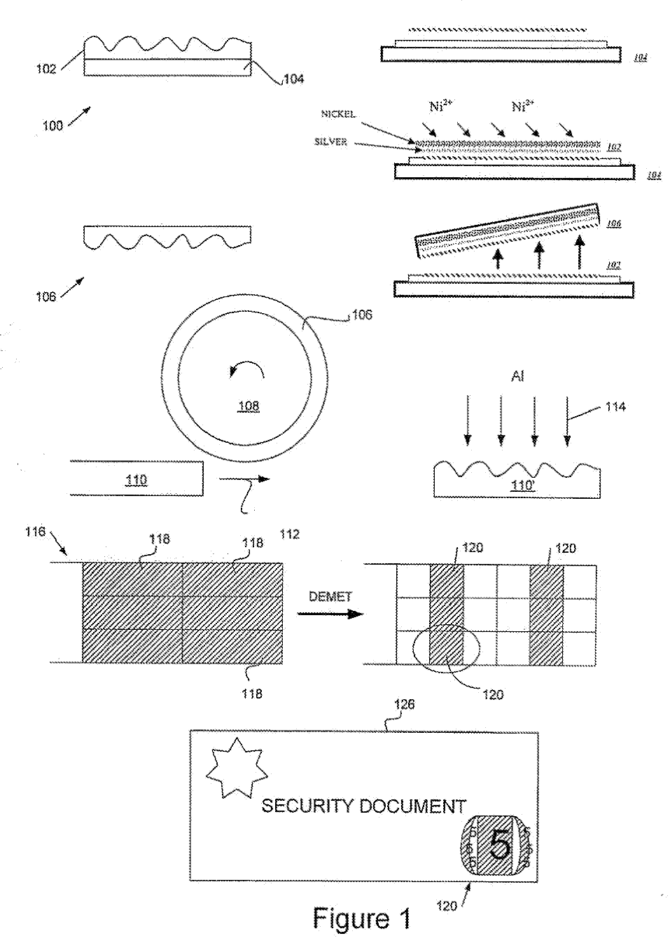

A typical process for applying an embossed hologram to a security document is shown in FIG. 1.

Referring to FIG. 1 a hologram 100 typically comprising an exposed and developed light or electron sensitive resist 102 on a glass substrate 104 has a coating of silver and then nickel electrode deposited to form a stamper plate 106. The stamper plate 106 is wrapped around a rotating drum 108 to emboss the diffraction structure onto a polyester film 110 moving in the direction of arrow 112. The film, can also act as a carrier for holograms embossed into some other material such as resin. The embossed film 110′ is then coated with aluminium 114, typically by sputtering, to form a tape 116 (shown in plan view) comprising a plurality of metallised holograms or “diffractive optical variable devices” (DOVDs) 118. These are cut into a length and stored on a reel. Typically tape 116 has a width of 3 or 4 cm and the metallised surface of tape 116 is provided with an adhesive to allow the holograms to be used for labelling or for hot stamping. The holograms 118 may optionally be selectively demetallised by means of a photoresist process and the demetallised holograms 120 are then cut up and attached to the substrate 126, such as a security document or bank note by hot stamping. With this process the aluminium metallisation is provided with a hot melt adhesive and polyester film 110 has two layers separated by a release layer such as wax. In this way; when the hologram-bearing film is heated the adhesive is melted, sticking the hologram to the substrate, and the wax is also melted, releasing the hologram from its film carrier.

There is, however, a need for improved methods of preparing holograms which need not necessarily involve heat (which can, in some instances, be destructive). There is a further need for security documents which are more tamper evident than hereto for.

According to a first aspect of the present invention there is therefore provided a method of preparing a hologram on a substrate, the method comprising: providing a hologram recording medium, the material comprising a carrier bearing a photosensitive hologram recording layer; recording a hologram in said photosensitive hologram recording layer;

applying an adhesive to said hologram recording layer; attaching said carrier bearing said hologram recording layer to a substrate using said adhesive; and removing said carrier to leave said hologram recording layer attached to said substrate by said adhesive.

The hologram recording medium may comprise any conventional hologram recording medium including, but not limited to, dichromated gelatine (DCG), silver halide, and photo polymer based materials. The step of recording the hologram generally involves exposing the hologram to interfering light beams followed by subsequent processing to “fix” the hologram. The particular processing steps after exposure it will be appreciated depend upon the recording layer and may comprise, for example, conventional developing techniques or other techniques such as (cross) polymerisation and/or baking. However it will be appreciated, that embodiments of the method need not require the application of heat, instead the application of the hologram to the substrate depending upon relative strengths of attachment of the recording layer to the carrier and to the substrate.

In embodiments adhesion of the photosensitive hologram recording layer to the adhesive is greater than adhesion of the layer to the carrier, at least in regions where it is desired to transfer the hologram to the substrate. However in variants of the method, described below, this condition is not required.

Preferably the adhesive comprises a transfer adhesive, that is broadly speaking a pressure sensitive adhesive on a carrier such as wax paper or coated tape arranged so that when the adhesive is placed in contact with the surface to which it is to be applied the adhesive, is transferred from the paper or tape carrier. Embodiments of the method employ “double-sided” adhesive, that is a thin layer of adhesive between two carriers such as wax paper and polyester.

The substrate to which the hologram is applied may comprise any suitable material including, but not limited to, glass, metal, paper and plastic; the carrier for the hologram recording material is typically polyester. The adhesion of the adhesive to the substrate is preferably greater than the adhesion of the photosensitive layer to the carrier.

In embodiments of the method the removing step includes tearing through the thickness of the hologram recording layer at one or more boundaries of the adhesive; for example the photosensitive layer may tear at the leading and trailing edges of the adhesive. Since the photosensitive layer is generally thin, even for so-called “thick” holograms (that is less than 100 μm in thickness, generally less than 10 μm in thickness) such a “tear” in practice provides a substantially clean edge.

In embodiments of the method adhesive may be applied to only a selected surface portion of the hologram recording layer; this may substantially correspond to a portion of that layer in which the hologram has been recorded.

It will be recognised from the foregoing description that the relative adhesion of the photosensitive hologram recording layer to the carrier and to the adhesive (layer) is important and this can be controlled by partial subbing of the carrier surface. Broadly speaking “subbing” refers to a base preparation or treatment of the carrier surface to which the photosensitive layer is to be attached. Without subbing a photosensitive recording layer on a substrate can easily become detached and in a conventional hologram, recording material subbing is therefore employed to prevent this. The subbing may be performed in one or more of a number of different ways including, but not limited to, mechanical roughening of the carrier surface, chemical treatment, treatment by a corona or electrostatic discharge, inclusion of an adhesive layer and the like. We will describe how, in embodiments of the methods partial subbing is employed to allow the carrier to be removed; this also has the advantage of making tampering with the resultant substrate-hologram combination more evident. This partial subbing may comprise subbing selectively applied to the carrier such that the subbing is reduced or absent in regions where the layer bearing the recorded hologram is to be attached to the substrate. However because holographic recording medium is generally manufactured in bulk such a selective subbing is less preferable than a substantially uniform partial subbing in which adhesion between the photosensitive layer and the carrier is reduced substantially uniformly over the area of the carrier so that the earner can be peeled away from the photosensitive layer bearing the hologram once this has been stuck to the substrate. Selective application of a hologram may then be achieved, among other ways, by selective application of the adhesive (layer).

In some preferred embodiments the surface treatment or “subbing” of tire carrier is applied in a pattern, preferably substantially uniformly across the surface of tire carrier which the photosensitive layer is applied. The pattern may comprise, for example, a pattern of dots, each dot defining a region of “subbing” surface treatment. The method may men comprise selecting a surface coverage or pattern for the surface treatment such that adhesion of the photosensitive hologram recording layer to the adhesive is greater than, the adhesion of the photosensitive layer to the carrier. For example in the case of a dot pattern the percentage of this coverage can be varied by selecting the dot size and/or spacing.

In a variant of the technique previously alluded to the surface treatment is reduced or substantially absent from a region of the photosensitive layer to be applied to the substrate. Then, when the carrier plus photosensitive layer is attached to the substrate by the adhesive some or all of the non-subbed (or treated) portion of the carrier plus recording layer is cut or stamped out. Then the subbed carrier plus photosensitive layer can be peeled away from the substrate plus adhesive (since the adhesion of the photosensitive layer to carrier where the carrier is subbed is stronger than that of the photosensitive layer to the adhesive). The portion of the carrier having a partially or non-subbed surface is notionally left in place above the photosensitive layer but is easily removed or, in practice, may simply fall away.

It will be appreciated that, broadly speaking, in the above described method the recorded hologram is transferred from the carrier to the substrate and, in the process, is turned upside down. This has the effect of converting the holographic image from an orthoscopic image into a pseudoscopic image, that is front/back and left/right reversing the image. In effect the hologram reconstructs from the opposite side, as if the reference beam was shifted by 180 degrees. An out of plane image recorded, say, by means of an LCD screen separated from the recording medium by a spacer so that the image is conventionally behind the plane of the hologram, when the hologram is inverted it appears in front of the plane of the hologram. For this reason in some preferred embodiments of the method the holographic image is substantially planar. Furthermore because of this pseudoscopic image reversal the technique is particularly applicable to biometric images in which a correct orientation of the image is not immediately apparent to a human viewer, such as an iris image and, especially, a finger print. Optionally the image recording may comprise recording of a pseudoscopic version of an image so that when the image is replayed it appears substantially as it would if conventionally recorded and reconstructed as an orthoscopic image.

In some particularly preferred embodiments of the method the photosensitive holographic recording layer comprises a recording layer for recording a volume hologram comprising in particular a volume reflection hologram; preferably then the recorded image comprises a volume (reflection) hologram. As the skilled person will appreciate broadly speaking a volume hologram is a hologram in which the angle between object and reference beams is equal to or greater than 90 degrees (although other definitions may be employed).

In another aspect the invention provides a product of a method as described above.

The invention further provides a holographic recording medium for recording a volume reflection hologram, the recording medium comprising: a carrier; a photosensitive hologram recording layer carried by said carrier; wherein mutual attachment of said photosensitive layer and said carrier is enhanced by a surface treatment of said carrier, and wherein said surface treatment is only partially applied to a surface of a said carrier bearing said photosensitive hologram recording layer.

The invention also provides a mounted hologram system comprising: a substrate;

a holographic recording layer in which a hologram has been recorded; an adhesive layer attaching said layer to said substrate; wherein said hologram comprises a volume hologram; and wherein said substrate is substantially non-transparent at a wavelength of operation of said holographic recording layer.

The operation of said holographic recording layer may comprise a recording or playback operation, and the wavelength of operation of the holographic recording layer may comprise (or be defined by) a recording or playback wavelength of the layer.

The invention further provides a mounted hologram system comprising: a substrate;

a holographic recording layer in which a hologram has been recorded; an adhesive layer attaching said layer to said substrate; and wherein an image reconstructed by said hologram comprises a pseudoscopic image.

The substrate may thus comprise a paper or plastic-based security document such as a passport, visa, identity card, driving license, government bond, bank note, Bill of Exchange or the like or some similar note, document, material or card such as packaging or labelling.

The Invention further provides a mounted hologram system comprising: a substrate;

a holographic recording layer in which a hologram has been recorded; an adhesive layer attaching said layer to said substrate; and wherein said substrate comprises a paper or plastic note document or card.

One advantage of embodiments of the above described method is that, if desired, a substrate-hologram system may be provided in which the photosensitive layer, attached by adhesive to the substrate, is exposed to the atmosphere, facilitating subsequent chemical or other treatment of the hologram. A protective layer may then be applied after such treatment.

In this specification references to light and to optics include ultraviolet and infrared light and optics as well as visible light/optics.

### Further Techniques and Systems

As previously mentioned, an increasingly important application for holograms is in the field of security, where a hologram may be used as an anti-counterfeiting device on security documents such as passports, visas, identity cards, driver licenses, government bonds, Bills of Exchange, banknotes and the like, as well as on packaging and labelling. To improve security special visual effects may sometimes be employed such as kinetic effects, for example the appearance/disappearance of graphic elements (sometimes termed Kinegram—Trade Mark), or contrast/brightness variation effects, for example a graphic converting from a positive to a negative image (a Pixelgram—Trade Mark). It will be appreciated, however, that there is scope for improved holographic techniques which contribute to increased security or which exhibit other desirable traits such as increased brightness and/or an improved visually aesthetic appearance.

The techniques we describe herein are suitable for use with a variety of different types of hologram. As an example we refer to volume reflection holography. Broadly speaking a reflection hologram is a hologram which is constructed by interfering object and reference beams which are directed onto a recording medium from opposite sides of the medium. As previously mentioned, broadly speaking a volume hologram is a hologram in which the angle difference between the object and reference beams is equal to or greater than 90 degrees. Volume holograms are sometimes referred to as “thick” holograms since, roughly speaking, the fringes are In planes approximately parallel to the surface of the hologram, although in practice the thickness of the recording medium can vary significantly, say between 1 μm and 100 μm, and is typically around 7 μm.

One property of volume holograms is that an image replayed by a volume hologram has a well-defined colour—that is when illuminated from a broadband source (or at the correct wavelength) it will reflect over only a narrow wavelength band the full width at half maximum of the peak depends upon the thickness of the recording medium, a thicker medium resulting in a narrower peak. Thus an image replayed by a volume hologram has a specific spectral colour; however more than one image may be stored and replayed and these different images may have different colours. To replay a stored image the angle of incident illumination must be approximately correct; if the hologram is tilted away from this correct angle the diffraction efficiency falls off rapidly (although the colour of the replayed image generally remains substantially the same).

Typical hologram, recording materials include (but are not limited to) dichromated gelatine (DCG), silver halide, and photopolymer based materials. This material is generally mounted on a carrier, typically polyester, although other carriers such as triacetate or cellulose nitrate may be used. The carrier is typically of the order of ten times the thickness of the gelatin emulsion, for example ˜75 μm thick, although carrier thickness can potentially range between ˜5 μm and ˜500 μm.

The step of recording the hologram generally involves exposing the hologram to interfering light beams followed by subsequent processing to “fix” the hologram. The particular processing steps after exposure it will be appreciated depend upon the recording layer and may comprise, for example, developing techniques similar to those used for conventional photographic film, or other techniques such as (cross) polymerisation and/or baking.

The further techniques we describe herein are suitable for use with any conventional holographic recording material and carrier, including but not limited to those described above, as well as with materials not conventionally used as holographic recording materials, for example materials of the type currently used for optical data storage disks, in particular those used for magneto-optic disks.

In a further aspect the invention provides a holographic recording medium including magnetic material, preferably ferro-magnetic material. This material is preferably in the form of small particles, for example less than 1 mm, 100 μm, 10 μm or 1 μm on average, in at least one dimension.

Preferably the magnetic materials are incorporated at such a level that the holographic recording medium is still relatively transparent at least one laser wavelength of interest, and preferably over a range of wavelengths of 100 nm, 200 nm, 300 nm, 400 nm, or more. Here transparent means a reduction in transmission caused by the incorporation of the magnetic material of less than 70 percent, more preferably less than 50 percent or 25 percent. This may be achieved, by the use of a substantially transparent magnetic materials or nanoscale magnetic particles.

Preferably where nanoscale particles are employed, for example ion oxide particles in the size range 1 nm to 1000 nm these particles are sufficiently asymmetric to define an orientation. For example the particles may be substantially one dimensional (rod or tube shape) or substantially two dimensional (lamellar).

In one embodiment these magnetic particles (or the magnetism of the magnetic material) is substantially aligned. This may be achieved, for example by aligning the particles during manufacture prior to curing the holographic recording media.

Any conventional recording medium, as mentioned above, may be employed.

The magnetism of the magnetic particles is preferably substantially aligned in the same way as the physical particles themselves. In some embodiments of the recording material the particles and/or magnetism can be re-aligned for example either by applying a magnetic field and/or by heating the holographic recording medium (either before or after the recording of one or more holograms in the medium).

in one embodiment the holographic recording medium comprises a carrier such as a polyester film on which is provided a photosensitive recording layer comprising, for example, a gel. In other embodiments silver halide or photopolymer may be employed.

We next describe methods of fabricating a hologram using a holographic recording medium incorporating magnetic material, in particular as described above.

Thus the invention provides a method in which a holographic recording medium including magnetic material has a hologram recorded in it, and in which the recording medium is processed, either before or after recording the hologram, to change the magnetic and/or physical alignment of the recording material.

In one embodiment a holographic recording material with aligned magnetic particles has a hologram recorded in it and then the alignment of the particles is changed to change the fringe spacing. For example disrupting the alignment can, in effect, swell the holographic recording material thus moving the fringe spacing towards the red. The processing and hologram recording steps can be reversed to provide a shift towards the blue. In another example the magnetic particles are orientated at a particular angle, for example 45 degrees, and then after recording a hologram the material may either by swollen or contracted by applying a magnetic field to move the particles orientation, for example towards 90 degrees or towards zero degrees (zero degrees being parallel to the plane of the hologram) to either swell or contract the material and thus shift the wavelength of any stored image towards either the red or the blue on replay. The process of changing the alignment may involve the application of heat and/or a magnetic field; optionally if necessary this may be assisted in some other way, for example by the temporary application of humidity and/or a solvent.

In the above described holographic recording medium and method materials/particles with an electric moment may be used instead of or in addition to materials/particles with a magnetic moment, in which case an electric field may be used to change the alignment of a particle. Broadly speaking the concept is to distort a holographic recording medium by the application of an external field in order to modify a material in which a hologram is recorded to bring about some advantageous effect. Thus the invention provides a hologram recording medium and method in accordance with this general principle.

It will be appreciated that embodiments of the above described media and methods are particularly suitable for volume holography, especially volume reflection holography.

The invention further provides hologram recording apparatus, for example along conventional lines, further incorporating means to apply a magnetic field and/or heat to change the alignment of magnetic material within a holographic recording medium.

A magnetic (or electric) holographic recording medium as described above may also be used to create a “covert” hologram.

Thus in another aspect the invention provides a method of recording a hologram in a holographic recording medium comprising a magnetically (or electrically) active material, the method comprising applying a magnetic (or electric) field to store a pattern within the holographic recording medium, in preferred methods heat or some other means of facilitating local magnetic orientation is applied to the recording medium, whilst the magnetic (or electric) field pattern is written and then the heat (or other facilitating means) is removed to effectively lock the pattern into the hologram.

For example in a material with a predetermined, say 45 degrees, alignment of particles a magnetic field and heat (or some other re-orientation facilitating treatment) may be applied to construct a pattern of orientation of the particles within the recording medium.

Thus the invention further provides a holographic recording medium of this type in which a patient for creating a hologram has been recorded. It will be appreciated that the “hologram” is stored covertly since this pattern is not yet itself a hologram.

To turn the pattern into a hologram the method may further comprise “developing” the pattern by applying a magnetic field and/or heat to convert, the pattern into a pattern of modulated refractive index (real and/or imaginary refractive index i.e. comprising transmission and/or refractive index modulation). Again some other treatment such as humidity and/or solvent or some other physical or chemical processing may be used additionally or alternatively to heat, and where particles with an electric moment are employed an electric field rather than a magnetic field may be used. Broadly speaking, in embodiments of the method the pattern of orientation is converted into a pattern of distortion of the holographic recording medium thus making the recorded “hologram” apparent. In embodiments of the method/recorded hologram this procedure may be reversible.

These and other aspects of the invention will now be further described, by way of example only, with reference to the accompanying figures in which:

FIG. 1 shows a typical process for applying an embossed hologram to a security document;

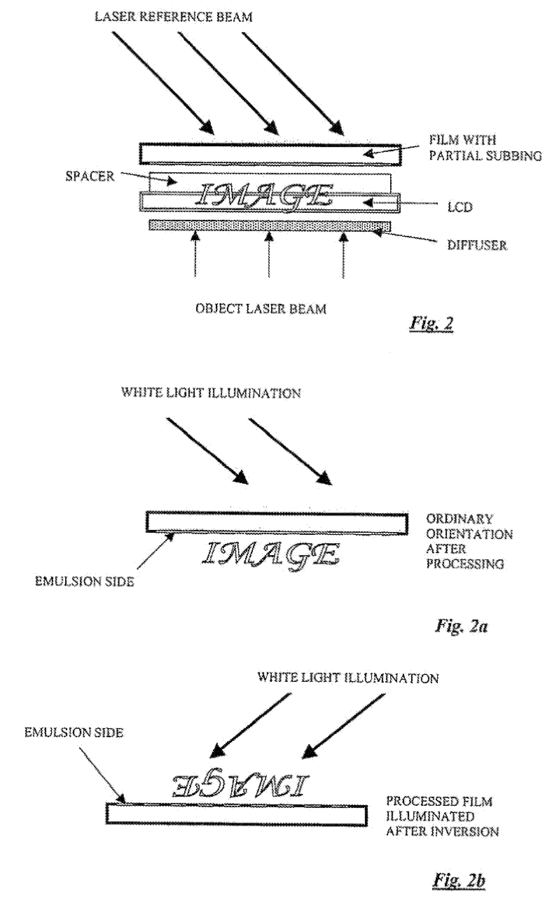

FIG. 2 shows steps in a procedure for preparing a hologram on a substrate embodying aspects of the present invention;

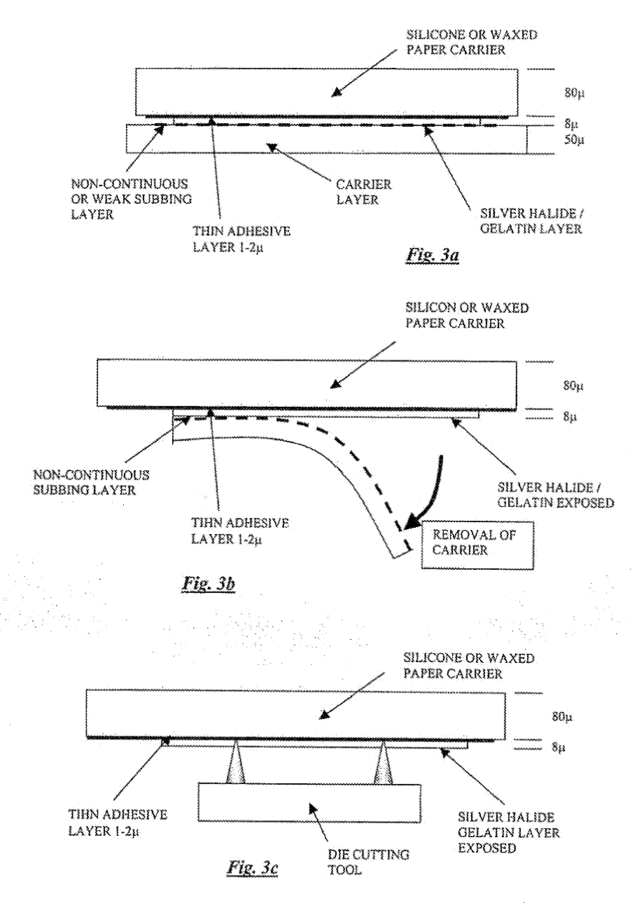

FIG. 3 shows an example of a holographic recording medium with partial subbing embodying an aspect of the present invention; and

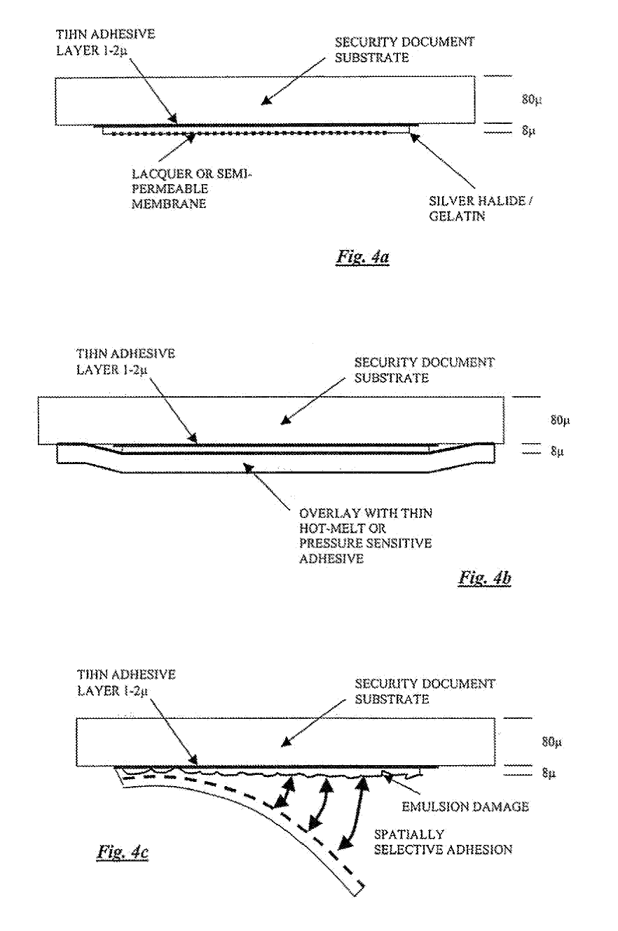

FIG. 4 shows an example of a substrate-mounted hologram embodying a further aspect of the invention.

As previously described, it is well known that the method of overlaying a security document such as a driving license or a cheque with a hologram, which is difficult to copy, can afford additional security value to that document.

Embossed holograms have been used during the last twenty years for security purposes and are applied to banknotes and other security documents in the form of a very thin layer of metallised lacquer. In order to improve the integrity of the device in, for example, the Bank of England currency notes, the metallised area of the attached film layer has been formed into a complex shape, rather than a simple square or circular area, by process called demetallisation. This prevents duplication by ordinary hot-foiling technology and eliminates an important counterfeiting method.

In the British passport document, embossed holography has been used in the form of a translucent thin layer coated on its reverse side with a layer of material such as zinc sulphide, whose refractive index is significantly higher than the carrier. Thus fight is reflected from the interface in such a way as to reconstruct the holographic image, whilst permitting the viewer to see simultaneously, printed matter behind the holographic film. Attempts to remove the covering layer will result in destruction of the hologram or the printed matter. Thus the Integrity of the layer is proven and the authenticity of a photographic portrait or printed alphanumeric below is confirmed.

The means of producing such a thin layer is well known as the technique of hot foiling. In this method, a layer of wax capable of melting only at a temperature in excess of the temperatures used in the hologram embossing process is applied to the carrier foil. Thus the phase image data, in the form of surface fringe relief microstructure, is actually carried in a thin lacquer attached to the carrier web by the wax layer. This surface relief structure can then be coated with a hot-melt adhesive so that under appropriate heat and pressure, the data carrying aluminised or “HRI” coated layer can be released from the polyester web and laid upon a paper or plastic security document, such as a cheque, banknote or credit-Card.

Embossing foils (“hot foils”) can be obtained from: Crown Foils Inc (HRI Foils), Kurz, DLR International, CFC, OVED Kinegram, Landis & Gyr, ABN, Giesecke & Devrient, AOT, TPF, and the like.

Embossed holograms however have two disadvantages as security devices. First they are mass-produced, facsimiles of a master embossing shim and as such are ail substantially identical. The nearest this technology has come to producing unique labels, is by the addition of laser printed or ablated enumeration, but these effects are strictly limited to surface-borne alphanumerics, etc., which in any ease be easily replicated in the ordinary course of print counterfeiting or copying. Second, after a number of years as front-Sine security devices there is an increasing tendency for them to be fraudulently simulated by the counterfeiting fraternity.

Reflection volume holograms, however, have the advantage that they are more difficult for the counterfeiter to make acceptable substitute copies, and most importantly they because they are recorded in ‘live’ photosensitive material at the mass-production stage, they may contain individually unique graphic content within the depth of the image. A serious difficulty inhibiting, the use of silver halide reflection holograms as & security device is the thickness of the layer associated with conventional silver halide gelatin coating technology. The use of conventional coating facilities where the photosensitive emulsion is applied to a web of material such as a polyester e.g. Polyethylene terphthalate (PET), means that minimum base thickness in excess of 50μ is required in order to enable the coating base web to run smoothly past the coating head in such a way as to present a predominantly flat surface for the uptake of the gelatin emulsion in order to produce a smooth coated layer of even thickness. A photographic or holographic film layer is normally regarded a complete single entity. However the base carrier is art inert material which simply provides a means of supporting the photosensitive gelatin layer during the critical processes of exposure to light and chemical processing of the resulting image. Our technique allows for the disposal of the inert carrier at a time subsequent to the preparation of the diffractive image within the active component of the layer.

We describe a means by which the superior security advantages of a silver halide reflection hologram can be made to find compatibility with the existing requirements of the security industry for such thin layers as those described above. It is important to note that there is a minimum requirement of thickness for reflection ‘volume’ holograms, which, by definition, contain phase information in a fundamentally different storage configuration to surface relief holograms.

As a result the minute thickness of hot foil hologram, which may be less than 5μ in total, is unachievable for a volume hologram if one is to retain the colour selective diffraction advantage that we prefer for our security device. Kogelnik's ‘coupled wave analysis’ indicates that for true monochromaticity, we may need an active fringe structure in excess of 20μ but the experimental results indicate that excellent diffractive properties can be achieved with silver halide gelatin emulsion layers of 7μ or less. Limitation of the thickness of the layer can be enhanced by the omission of the ‘supercoat’ or ‘non-stress’ plain gelatin layer, which is frequently added to silver halide assembled to protect the photosensitive components from mechanical abrasion, since the delicate holographic layer will, in any case, need to be otherwise protected from such abrasion during the handling processes prior to it lamination into a security document.

The successful preparation of photographic materials generally depend upon the ability of the coating equipment to produce a smooth layer of even thickness, which is well bonded to the carrier web. The result of coating a gelatin emulsion onto an unprepared polyester base will be a lack of adhesion between the gelatin layer and the extremely smooth surface of the polyester base.

Since photographic developers are almost invariably alkaline aqueous solutions, the gelatin layer will expand during the processing stage to many times its original thickness, and as a result of the mechanical changes going on at the interface of the polyester and the gelatin emulsion, an unprepared union will tend to divide. The technique of ‘subbing’ allows for pre-treatment of the surface of the polyester or other carrier, so as to disrupt or coat its smooth surface to allow for the gelatin to form a strong bond which will not allow for the layers to separate at any time after the coating process is complete.

However our technique allows for a deliberate reduction in the permanence or strength of this bond in such a way as to allow for the hologram exposure by laser and the chemical processing to proceed in the ordinary way, to be followed by the deliberate separation for the thin gelatin layer by the provision of an adhesive bond to its free surface or greater strength than the bond between it and the original carrier. An example of a suitable adhesive layer is a pressure sensitive adhesive such as those supplied by Mac-Tac (Soignies, Belguim Northampton England) or Fasson/Avery or a hot melt layer of the type used in the British passport overlay.

Having bonded the exposed surface of the gelatin layer to such a ‘transfer adhesive’ we can then selectively remover the original thick (>50μ) carrier layer at a convenient point, so as to coat a new thin protective layer (lacquer) to the newly exposed gelatin in order to protect it from mechanical abrasion or exposure, to moisture, whilst retaining the property that this is now a significantly thinner layer. This layer may have complex properties such, as partial permeability in order to allow special chemicals in the form of gases or fluids to interact with the layer or components of the layer. Alternatively we can coat a second adhesive on the second face of the gelatin such that we have a label now which is ‘sticky’ on both sides and as such can be applied as a component of a ‘sandwich assembly’ in a variety of security application such as plastic cards, passport overlays and product authenticity labels.

During the process of manipulation of the gelatin layer regarding its removal from the original base and relaying into other carrier assemblies and final lamination into document substrates the holographic image may be viewed from either side of the original exposure configuration, and it is necessary to pre-reverse the perspective and left/right handing of the image by manipulation of the graphics, reference angles and exposure side, etc. It is well understood that a ‘pseudoscopic’ holographic image results from an inversion of the carrying medium with respect to the illumination and viewing positions. Such effects can be corrected by inversion of artwork graphics etc., and such changes can be made in software image processing and exposure configuration to ensure that the required correct perspective will be seen In the finished product.

The process genetically called ‘subbing’ here refers to various techniques which can each offer ways of achieving the partial or selective levels of adhesion required by this invention. For example ‘corona’ treatment of base material results in microscopic disruption of the surface which may allow ‘keying’ of the substrate such that a thin priming coating of a gelatin solution may be applied to the base as a preparatory treatment before the base material is supplied to the coating laboratory. We use various means to achieve ‘partial’ adhesion to the photosensitive holographic gelatin emulsion. This partial adhesion may be achieved by either spatial reduction of the proportion of the surface, which is physically or chemically treated, by a method similar to the dot-screening process for ‘half tone’ printing or by a selective reduction in the actual amplitude of the chemical or physical adhesive bond between the subbing and emulsion layer.

For example the intensity of ‘corona treatment’ may be reduced by the use of a masking technique to prevent exposure of electrons reaching the whole surface of the carrier layer in the form of a matrix of dots of alternate absorption and transmission of radiation into the substrate below. Alternatively, the level of adhesion may be reduced by a simple reduction in the exposure time to the radiation, such that the surface receives a spatially continuous treatment but at a reduced level in terms of time or amplitude.

Additionally or alternatively the concentration or chemical constituents of a primer layer may be adjusted to selectively reduce adhesion. Simple dilution of a gelatin solution for example may be responsible for a lower coating weight and thus less substantive chemical bonding to either the base substrate or the gelatin emulsion to be coated.

Additionally or alternatively, substituted gelatins for example, whose characteristics are affected by pH, could be used with the intention that a post processing bath with a specific pH or other chemical characteristics being applied to the hologram, to reduce the effectiveness of the adhesive bond between the gelatin and the carrier.

Referring now to FIG. 2 this shows the use of a laser beam divided at a beamsplitter to provide two mutually coherent beams. These are arranged to illuminate, from opposing sides, an assembly comprising a diffuser, an LCD panel, a translucent spacer made from glass, quartz or other non-birefringent material, and the special recording film made in accordance with the new technique.

The film is moved into position by a transport system and held still during laser exposure by sandwiching with a glass plate or the optional use of a vacuum chuck or other means.

One of these laser beams is expanded by a spatial filter and fails upon the diffuser. The LCD panel then spatially modulates the transmitted diffuse light. This beam is designated the object beam in accordance with holographic convention. The other beam is also suitably expanded through a spatial filter is delivered obliquely to the carrier side of the film. The angle of incidence is known as the reference angle. The standing wave of interference between these beams forms a series of parallel planes of light and dark which are in one plane, at least, parallel with the photosensitive recording layer.

A device where a significant number of such fringes is known as a volume reflection hologram and has the useful property that it will reflect only a narrow band of wavelengths. It can thus produce an image, which is clearly visible in white light, and does not suffer from chromatic dispersion and smearing associated with transmission holography. Furthermore, this is a three dimensional image since both the phase and amplitude of light from the object beam is recorded.

After chemical processing the holographic film may be illuminated aid viewed from either side, and an orthoscopic or pseudoscopic image will be seen as shown in FIGS. 2a and 2b respectively. In accordance with the requirements of the final product, we can manipulate the object information and the film inversion prior to exposure to achieve a satisfactory image for the final product configuration, when the sequence of handling processes for the film and its photosensitive layer is established.

FIG. 3a shows the application of a thin layer of adhesive to the holographic film, in one embodiment, this is a pressure sensitive adhesive attached to a waxed or silicone paper carrier. The adhesive attaches sufficiently firmly to the gelatin layer to enable the original partially subbed carrier to be removed as shown in FIG. 3b.

FIG. 3c shows one method to ensure that a well-defined edge is achieved in the final application of the diffractive device to a security document. The die-cutting tool is able to delineate the precise shape of gelatin emulsion, which will transfer to the final document. The blade pierces the gelatin, but the tool may optionally cut through the carrier in order to stamp out an individual label as an alternative to leaving the labels on the web for applications associated with mass production methods. After the label shapes have been die stamped through the gelatin, it is a well-known technique to “remove the ladder” by carefully releasing the waste web at a correct rate in association with the correct curvature of the carrier at the apex of a transport roller.

FIG. 4 shows the application of the device to a security document in three various embodiments. In FIG. 4a we see an application to a document where the thin layer is fixed to a document such as a cheque or banknote such that it can be sealed with a lacquer or other thin layer. This may create a non-permeable or semi-permeable protective layer to provide durability, prevent finger marking, and add resistance to abrasion or chemicals. In some applications, ingress of certain species may be desirable and a lacquer could be designed to accommodate such a requirement.

FIG. 4b shows an application of me technique, which might be used in a document such as a passport. In this embodiment the thin label is applied to the paper document and the overlay, which may contain a hot-melt adhesive on its inner surface to complete the lamination process. Alternatively, the thin device could be attached to the overlay, which is then coated with adhesive including the obverse of the hologram device, before application to the paper document In this case account will need to be taken of the layer reversal, so that the image is right reading in its final configuration, by means of pre-reversal of the artwork at the image recording stage.

FIG. 4c, shows a quite different use of the technique whereby the material is partially subbed in a spatially modulated way, for example in the shape of a repetitive logo. The overall level of adhesion of the gelatin emulsion to the carrier base is relatively high in this case. The hologram, including its original carrier base, is coated with secure adhesive on its gelatin emulsion side, and is applied to the final document surface. After curing of the adhesive, with its strong bond to the paper and gelatin layer, any attempt to remove the diffractive security layer, results in de-lamination of the bond between the partially subbed carrier and the gelatin and causes destructive distortion of the photosensitive layer, which may give rise to the appearance of a distinct pattern in the brightness, colour or homogeneity of the remaining holographic image.

No doubt, many other effective alternatives will occur to the skilled person. It will be understood that the invention is not limited to the described embodiments and encompasses modifications apparent to those skilled in the art lying within the spirit and scope of the claims appended hereto.

1-19. (canceled)

20. A method of preparing a hologram on a substrate, the method comprising:
providing a hologram recording medium, the material comprising a carrier bearing a photosensitive hologram recording layer;
recording a hologram in said photosensitive hologram recording layer;
applying art adhesive to said hologram recording layer;
attaching said carrier bearing said hologram recording layer to a substrate using said adhesive; and
removing said carrier to leave said hologram recording layer attached to said substrate by said adhesive.

21. A method as claimed in claim 20 wherein said adhesive applying comprises applying said adhesive to only a selected surface portion of said hologram recording layer.

22. A method as claimed in claim 21 wherein said hologram is recorded in only part of said hologram recording layer, said selected surface portion of said hologram recording layer substantially corresponding to said part of said hologram recording layer within which said hologram is recorded.

23. A method as claimed in claim 20 wherein said removing includes tearing through a thickness of said hologram recording layer at one or more boundaries of said adhesive.

24. A method as claimed in claim 20 wherein adhesion of said photosensitive hologram recording layer to said adhesive is greater than adhesion of said photosensitive layer to said carrier.

25. A method as claimed in claim 20 wherein said adhesive comprises a transfer adhesive.

26. A method as claimed in claim 20 wherein mutual attachment of said photosensitive layer and said carrier is enhanced by a surface treatment of said carrier, and wherein said surface treatment is only partially applied to a surface of said carrier bearing said photosensitive hologram recording layer.

27. A method as claimed in claim 26 wherein said surface treatment is applied in a pattern.

28. A method as claimed in claim 27 wherein said pattern comprises a pattern of dots partially covering said surface of said carrier bearing said photosensitive hologram recording layer.

29. A method as claimed in claim 26, the method further comprising selecting a surface coverage of said surface treatment such that adhesion of said photosensitive hologram recording layer to said adhesive is greater than adhesion of said photosensitive layer to said carrier.

30. A method as claimed In any claim 20 further comprising cutting through at least said carrier prior to said removing.

31. A method as claimed in any claim 20 wherein said recording comprises recording a pseudoscopic version of an image for reply by said hologram on said substrate.

32. A method as claimed in any claim 20 wherein said photosensitive holographic recording layer comprises a recording layer for recording a volume hologram, in particular a volume reflection hologram.

33. A holographic recording medium for recording a volume reflection hologram, the recording medium comprising:
a carrier;
a photosensitive hologram recording layer carried by said carrier;
wherein mutual attachment of said photosensitive layer and said carrier is enhanced by a surface treatment of said carrier, and wherein said surface treatment is only partially applied to a surface of a said carrier bearing said photosensitive hologram recording layer.

34. A mounted security hologram system comprising:
a substrate;
a holographic recording layer in which a hologram has been recorded;
an adhesive layer attaching said layer to said substrate;
wherein said hologram comprises a volume reflection hologram; and
wherein said substrate is substantially non-transparent at a wavelength of operation of said holographic recording layer.

35. A mounted security hologram system comprising:
a substrate;
a holographic recording layer in which a volume reflection hologram has been recorded;
an adhesive layer attaching said layer to said substrate; and
wherein an image reconstructed by said volume reflection hologram comprises a pseudoscopic image.

36. A mounted security hologram system as claimed in claim 34, wherein said substrate comprises a paper or plastic note, document or card.

37. A security hologram system as claimed in claim 34 wherein said holographic recording layer is exposed to the atmosphere.

38. A security hologram system as claimed in claim 35, wherein said holographic recording layer is exposed to the atmosphere.
